(19) United States
(12) Patent Application Publication
(10) Pub. No.: US 2012/0163131 A1
(43) Pub. Date: Jun. 28, 2012

(54) Mono-directional Ultrasound Transducer for Borehole Imaging

(75) Inventor: Scott KENNEDY, Phoenix, AZ (US)

(73) Assignee: SONDEX LIMITED, Yately (GB)

(21) Appl. No.: 12/976,278

(22) Filed: Dec. 22, 2010

(51) Int. Cl. H04R 17/00; H01L 41/22; G10K 9/125

(52) U.S. Cl. 367/157; 310/336; 29/25.35

(57) ABSTRACT

Devices and methods to generate a mono-directional ultrasonic wave are provided. An ultrasonic sensor configured to emit a substantially mono-directional ultrasonic wave includes a first piezoelectric element and a second piezoelectric element. The first piezoelectric element is configured to generate a first ultrasonic wave propagating in a first direction and a second ultrasonic wave propagating in a second direction which is different from the first direction. The second piezoelectric element is located and configured to absorb the second ultrasonic wave, and is configured to convert an energy of the absorbed second ultrasonic wave into an electrical energy.

### BACKGROUND

1. Technical Field

Embodiments of the subject matter disclosed herein generally relate to ultrasonic transducers and ultrasonic methods usable for borehole imaging, more particularly, to devices and techniques using a piezoelectric element to absorb backwards ultrasonic waves.

2. Discussion of the Background

Since oil and gas remain a source of energy that cannot be replaced at a significant enough proportion in the world economy, the interest in developing new production fields has continued to increase, in spite of the harsher conditions in terms of accessibility and safety of exploitation. Ultrasonic measurements inside oil and gas wells are often desirable because they give access to information related to the size and configuration of a well casing, sides of the well, etc. In order to collect this information, a probe or “sonde” having one or more ultrasonic transducers attached may be lowered into the borehole inside the casing or prior to the installation of the casing. An ultrasonic transducer emits ultrasonic waves, and may detect echoes of the emitted ultrasonic waves that are reflected back to the transducer.

If the transducer emits a spherical wave, the echo received will be phase-shifted depending on a distance between the transducer and each of the locations from which the wave is reflected. Differentiation of echoes of the spherical wave that are reflected from different directions is impractical. Thus, it is preferred using collimated, plane ultrasonic waves.

A plane surface of a piezoelectric disc may emit ultrasonic waves having a satisfactory directionality. However, the piezoelectric disc emits ultrasonic waves both in a forward (desired) direction and in a backward direction (opposite to the forward direction). The forward propagating waves and the back-propagating waves are emitted simultaneously by the piezoelectric disc, and have the same frequency and signal shape. An echo of the forward propagating waves and an echo of the back-propagating waves are practically indistinguishable.

Many ultrasonic wave focusing techniques are available and have been used in developing conventional sensors in attempts to achieve an ideal mono-directional (i.e., only forward propagating) ultrasonic source. However, the issue of back-propagating waves has not been solved in a satisfactory manner. One conventional manner of addressing this issue is including a few inches thick absorber in the transducer, the absorber being located in the backward propagating direction relative to the piezoelectric disc. The absorber may be made of absorptive rubber and high impedance tungsten. Due to the large absorber, such a transducer is heavy and bulky.

Accordingly, it would be desirable to provide a transducer able to provide a mono-directional ultrasonic wave that avoids the afore-described problems and drawbacks.

### SUMMARY

According to one exemplary embodiment, an ultrasonic sensor includes (a) a first piezoelectric element configured to generate a first ultrasonic wave propagating in a first direction, and a second ultrasonic wave propagating in a second direction different from the first direction, and (b) a second piezoelectric element located and configured to absorb a part of the second ultrasonic wave that reaches the second piezoelectric element, and configured to convert an energy of the absorbed second ultrasonic wave into an electrical energy.

According to another exemplary embodiment, an ultrasonic transducer includes an active piezoelectric element, a passive piezoelectric element, a first electrical circuit, a second electrical circuit, and a housing. The active piezoelectric element is configured to receive an electrical signal and to covert the received electrical signal into a first ultrasonic wave propagating in a first direction and a second ultrasonic wave propagating in a second direction different from the first direction. The passive piezoelectric element is located and configured to absorb a remaining part of the second ultrasonic wave that reaches the passive piezoelectric element, and is configured to convert the absorbed second ultrasonic wave into an electrical energy. The reflecting layer is located between the active piezoelectric element and the passive piezoelectric element, and is configured to reflect a part of the second ultrasonic wave, in the first direction. The first electrical circuit is connected to opposite faces of the active piezoelectric element and is configured to provide the electrical signal to the active piezoelectric element. The second electrical circuit is connected to opposite faces of the passive piezoelectric element, and includes a resistance configured to dissipate the electric energy. The housing is configured to encase the active piezoelectric element, the passive piezoelectric element, the reflecting layer, the first electrical circuit, and the second electrical circuit.

According to another exemplary embodiment, a method of manufacturing an ultrasonic sensor includes mounting, in a holding structure, an active piezoelectric element configured to emit ultrasonic waves in opposite directions, and a passive piezoelectric element configured to absorb an ultrasonic wave emitted by the active piezoelectric element towards the passive piezoelectric element.

According to another exemplary embodiment, a method of generating mono-directional ultrasonic waves includes emitting ultrasonic waves that propagate substantially in two different directions by an active piezoelectric element, and absorbing the ultrasonic waves propagating in one of the two directions by a passive piezoelectric element.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a transducer according to an exemplary embodiment;

FIG. 2 is a flow chart illustrating a method of producing an ultrasonic sensor according to an exemplary embodiment; and

FIG. 3 is a flow chart illustrating a method for generating mono-directional ultrasonic waves according to an exemplary embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of a transducer usable in a borehole of a well drilled for oil and gas. However, the embodiments to be discussed next are not limited to these systems, but may be applied to other systems that require the supply of a mono-directional ultrasonic transducer.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

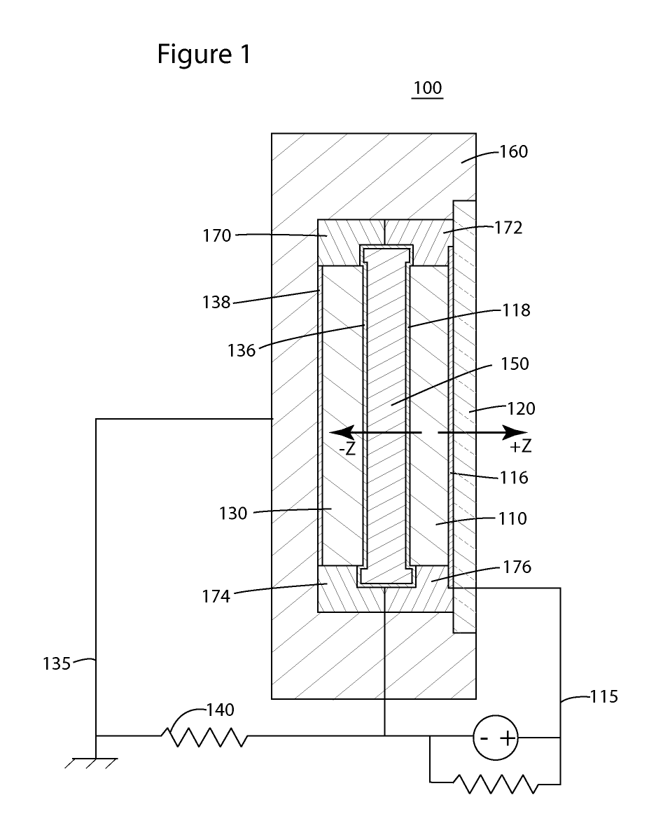

According to an embodiment, FIG. 1 illustrates a transducer 100 having an active piezoelectric element 110 (on the right side in FIG. 1) that emits ultrasonic waves upon receiving an electrical signal. The active piezoelectric element 110 may have a cylindrical shape (i.e., it is a disc), for example, of about 1 inch diameter and about 0.156 inches thickness. The thickness of the active piezoelectric element 110 can be used to tune the frequency of the generated ultrasonic waves. For example, if the piezoelectric element 110 is about 0.156 inches thick, the ultrasonic waves may have a frequency of about 500 kHz. However, other values may be selected.

The active piezoelectric element 110 may emit ultrasonic waves having a square, sinusoidal or pseudo-sinusoidal time evolution (i.e., shape) lasting from 1 to 2 cycles, and a maximum amplitude limited only by the breakdown field of the active piezoelectric element 110 (the breakdown field depending on both the material and the dimensions of the piezoelectric element). The active piezoelectric element 110 may also detect echoes of the emitted ultrasonic waves. A distance from the active piezoelectric element 110 to a reflection surface (e.g., the side of the well) is evaluated based on a time of flight, which is the time interval between when the ultrasonic signal is emitted and when the echo is detected. Distances between different reflecting surfaces can be estimated based on time differences between when the different respective echoes are detected. A rotating or otherwise scanning transducer can yield an image of the borehole surface, revealing features in rock formation or, in a lined borehole, damage to the metal casing, etc. The prior art transducer, which is bulky and thick due to the large absorbers stacked behind the active piezoelectric element, is difficult (if possible) to operate in this manner (i.e., to rotate it in order to visualize the borehole side).

An electric circuit 115 is connected to the active piezoelectric 110 to provide an electrical signal causing the active piezoelectric element 110 to emit the ultrasonic waves. An ultrasonic echo absorbed by the active piezoelectric element 110 and converted into an electrical echo signal may be picked-up (e.g., to have the echo's time of flight measured) also in the electric circuit 115.

A window 120 may be mounted on the active piezoelectric element 110 in a forward propagation direction (+z). The window 120 is configured to have an ultrasonic impedance matching an ultrasonic impedance of the fluid (e.g., water) in the borehole, thereby minimizing reflection or dispersion of the ultrasonic wave propagating from the active piezoelectric element 110 through the window 120 to the borehole fluid. For example, the window 120 may be made of polyphenylene sulfide (PPD) with embedded glass, which has favorable acoustical impedance properties and exhibits stability under high pressures that may exceed 1000 atmospheres, and high temperatures that may be encountered in a borehole. The window 120 may advantageously have a thickness equivalent to a quarter of the ultrasonic wavelength (λ). For example, the window 120 may be 0.059 inch thick. The thickness of the window may be used to tune a response of the transducer by providing a more broadband reception of signals when used in dispersive media.

The active piezoelectric element 110 generates ultrasonic waves both in the forward direction +z, which is the intended propagation direction, and in a backward direction −z. The transducer 100 further includes a passive piezoelectric element 130 similar to the active piezoelectric element 110 in terms of dimensions and resonant frequency, which is placed substantially parallel with the active piezoelectric element 110 in the backward direction. This passive piezoelectric element 130 is configured to absorb the backward propagating waves emitted by the active piezoelectric element 110, and to convert the mechanical energy of the backward propagating waves into electric energy. This electric energy is then dissipated as heat in an electric circuit 135 that includes a resistor 140.

Thus, instead of thick and bulky absorbers conventionally used to damp the back-propagating ultrasonic wave, the passive (i.e., not emitting ultrasonic waves) piezoelectric element 130 is used to absorb the back-propagating ultrasonic waves. Using another (passive) piezoelectric element as absorber results in a smaller (weight-wise and dimensional) transducer than the conventional transducers with the thick and bulky absorbers. The transducer 100 is also more efficient in eliminating the back-propagating ultrasonic waves.

In order to electrically connect circuits 115 and 135 to the active piezoelectric element 110 and the passive piezoelectric element 130, respectively, opposite surfaces of the active piezoelectric element 110 and of the passive piezoelectric element 130 are covered with conductive layers 116, 118, 136 and 138, respectively. The surfaces covered by the conductive layers may be perpendicular to the forward and the backward propagation directions. The conductive layers 116, 118, 136 and 138 may be made of copper, silver, gold, etc., and may have thicknesses in a range of 5-10 μm.

In order to increase the efficiency of eliminating the back-propagating ultrasonic waves and enhance the efficiency of emitting the forward propagating ultrasonic waves, a reflecting layer 150 may be mounted between the active piezoelectric element 110 and the passive piezoelectric element 130. The reflecting layer 150 is configured to reflect a part of the back-propagating ultrasonic wave at a surface between the reflecting layer 150 and the active piezoelectric element 110. The reflecting layer 150 may be made of tungsten, which due to its acoustic impedance and ¼ lambda filter characteristic may reflect up to 50% of the backward propagating wave. For example, the thickness of the tungsten layer may be 0.107 inch. The part of backward propagating wave reflected at the interface between the active piezoelectric element 110 and the reflecting layer 150 may constructively interfere with the forward propagating wave. The reflecting layer 150 may have an acoustic thickness equivalent to an odd number of quarter wavelengths.

The reflecting layer 150 may be covered by a conductive layer or may be a conductor itself, thereby electrically connecting conductive layers 118 and 136, at a potential different from the ground potential.

The transducer 100 may include a housing 160 having an opening for the window 120, and being configured to encase the active piezoelectric element 110, the passive piezoelectric element 130 and the reflecting layer 150. The housing 160 may be made of steel or another material capable to withstand borehole conditions, having a good resistance to abrasion and chemical attacks. When the housing is made of steel, the circuit 135 may be electrically connected to the conductive layer 138 via the housing 160, as in FIG. 1.

Mounting parts 170, 172, 174, and 176 may be disposed inside the housing 160, and may be configured to electrically isolate the conductive layer 116 from the conductive layer 118, and the conductive layer 136 from the conductive layer 138 (i.e., the conductive layers that cover the opposite surfaces of the active piezoelectric element 110 and of the passive piezoelectric element 130, respectively). For example, the mounting parts 170, 172, 174, and 176 may be made of polyphenylene sulfide (PPS).

The active piezoelectric element 110, the passive piezoelectric element 130, the reflecting layer 150 and the mounting parts 170, 172, 174, and 176 may be assembled inside the housing 160 to form a compact rectangular object with the window 120 in the forward (desired) ultrasonic waves propagating direction.

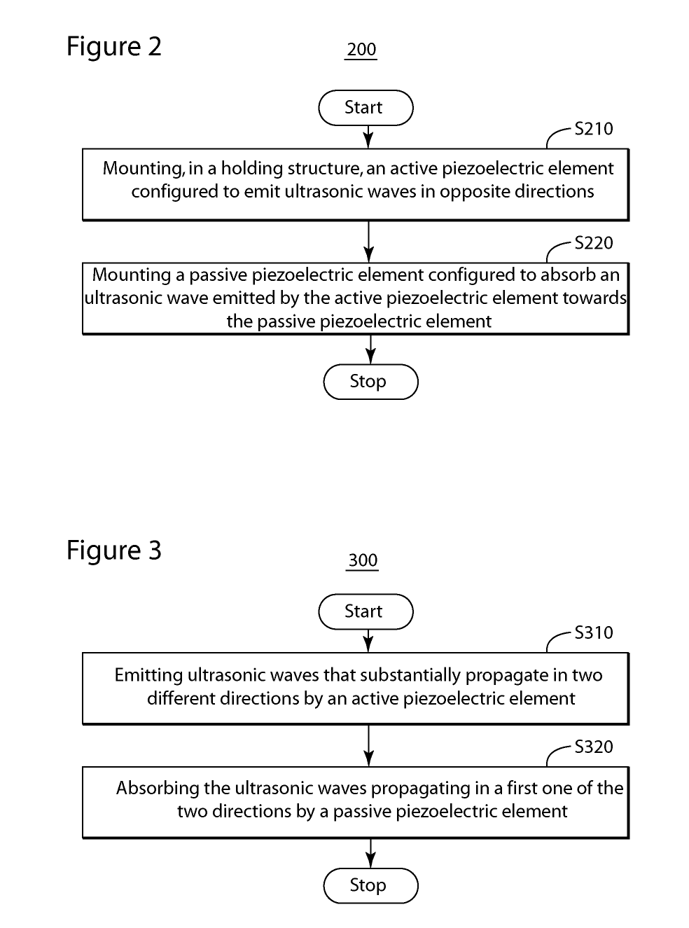

An ultrasonic sensor similar to the transducer 100 in FIG. 1, may be produced by a method 200 of manufacturing an ultrasonic sensor whose flow chart is illustrated in FIG. 2. The method 200 includes mounting, in a holding structure (e.g., 160 in FIG. 1), an active piezoelectric element (e.g., 110 in FIG. 1) configured to emit ultrasonic waves in opposite directions, at S210. The method 200 further includes mounting a passive piezoelectric element (e.g., 130 in FIG. 1) configured to absorb an ultrasonic wave emitted by the active piezoelectric element (e.g., 110 in FIG. 1) towards the passive piezoelectric element (e.g., 130 in FIG. 1), at S220. The passive piezoelectric element (e.g., 130 in FIG. 1) may be mounted substantially parallel with the active piezoelectric element (e.g., 110 in FIG. 1).

The method 200 may also include mounting a reflecting layer (e.g., 150 in FIG. 1) between the active piezoelectric element (e.g., 110 in FIG. 1) and the passive piezoelectric element (e.g., 130 in FIG. 1), the reflecting layer (e.g., 150 in FIG. 1) being configured to reflect a part of the ultrasonic wave emitted by the active piezoelectric element towards the passive piezoelectric element.

The method 200 may also include applying conductive layers (e.g., 116, 118, 136 and 138 in FIG. 1) on opposite surfaces of the active piezoelectric element (e.g., 110 in FIG. 1) and of the passive piezoelectric element (e.g., 130 in FIG. 1). The surfaces covered by the conductive layers may be perpendicular to the propagation directions of the ultrasonic waves emitted by the active element.

The method 200 may also include connecting the conductive layers (e.g., 136 and 138 in FIG. 1) applied on opposite surfaces of the passive piezoelectric element (e.g., 130 in FIG. 1) to an electrical circuit (e.g., 135 in FIG. 1) including a resistance (e.g., 140 in FIG. 1).

The method 200 may further include mounting one or more mounting components (e.g., 170, 172, 174 and 176 in FIG. 1) configured to electrically isolate the conductive layers (e.g., 116 and 118, and 136 and 138 in FIG. 1) applied on the active piezoelectric element (e.g., 110 in FIG. 1) and on the passive piezoelectric element (e.g., 130 in FIG. 1), respectively.

The method 200 may also include mounting a window element (e.g., 120 in FIG. 1) on the active piezoelectric element (e.g., 110 in FIG. 1) on a side opposite to a side towards the passive piezoelectric element (e.g., 130 in FIG. 1), the window element (e.g., 120 in FIG. 1) being configured to have an acoustic impedance matching an acoustic impedance of a fluid inside a borehole.

FIG. 3 is a flow diagram of a method 300 of generating mono-directional ultrasonic waves usable in a borehole. The method 300 includes emitting ultrasonic waves that propagate substantially in two different directions by an active piezoelectric element (e.g., 110 in FIG. 1) at S310. The method 300 further includes absorbing the ultrasonic waves propagating in one of the two directions by a passive piezoelectric element (e.g., 130 in FIG. 1), at S320.

The method 300 may further include converting an energy of the absorbed ultrasonic waves into electric energy by the passive piezoelectric element (e.g., 130 in FIG. 1), and dissipating the electric energy by a resistance (e.g., 140 in FIG. 1) in a circuit (e.g., 135 in FIG. 1) connected to the passive piezoelectric element (e.g., 130 in FIG. 1).

The method 300 may also include reflecting in another one of the two directions, a part of the ultrasonic waves propagating in the one of the two directions, by a reflecting layer (e.g., 150 in FIG. 1) located between the active piezoelectric element (e.g., 110 in FIG. 1) and the passive piezoelectric element (e.g., 130 in FIG. 1).

The disclosed exemplary embodiments provide devices, methods of manufacturing the devices and methods for generating mono-directional ultrasonic waves. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. An ultrasonic sensor, comprising:
a first piezoelectric element configured to generate a first ultrasonic wave propagating in a first direction, and a second ultrasonic wave propagating in a second direction different from the first direction; and
a second piezoelectric element located and configured to absorb a part of the second ultrasonic wave that reaches the second piezoelectric element, the second piezoelectric element being configured to convert an energy of the absorbed second ultrasonic wave into an electrical energy.

2. The ultrasonic sensor of claim 1, further comprising:
a reflecting layer located between the first piezoelectric element and the second piezoelectric element and configured to reflect a part of the second ultrasonic wave in the first direction.

3. The ultrasonic sensor of claim 2, wherein the reflecting layer is made of tungsten.

4. The ultrasonic sensor of claim 2, wherein the reflecting layer has an acoustic thickness equivalent to an odd number of quarters of a wavelength of the first and second ultrasonic waves.

5. The ultrasonic sensor of claim 1, wherein the second piezoelectric element is substantially similar to the first piezoelectric element.

6. The ultrasonic sensor of claim 1, further comprising:
an electrical circuit connected to opposite faces of the second piezoelectric element and including a resistance configured to dissipate the electric energy.

7. The ultrasonic sensor of claim 1, wherein opposite surfaces perpendicular to the first and the second propagation directions of the first piezoelectric element and of the second piezoelectric element are covered with conductive layers configured to be connected to electrical circuits.

8. The ultrasonic sensor of claim 7, further comprising:
one or more mounting parts configured to electrically isolate from each other the conductive layers that cover the opposite surfaces of the first piezoelectric element and of the second piezoelectric element, respectively.

9. The ultrasonic sensor of claim 1, further comprising:
a window element mounted on the first piezoelectric element in the first direction and configured to have a thickness equivalent to a quarter of an wavelength of the first and second ultrasonic waves and to withstand borehole conditions.

10. The ultrasonic sensor of claim 9, wherein the window element is made of polyphenylene sulfide.

11. An ultrasonic transducer, comprising:
an active piezoelectric element configured to receive an electrical signal and to covert the received electrical signal into a first ultrasonic wave propagating in a first direction and a second ultrasonic wave propagating in a second direction different from the first direction;
a passive piezoelectric element located and configured to absorb a remaining part of the second ultrasonic wave that reaches the passive piezoelectric element, and configured to convert the absorbed second ultrasonic wave into an electrical energy;
a reflecting layer located between the active piezoelectric element and the passive piezoelectric element and configured to reflect a part of the second ultrasonic wave, in the first direction;
a first electrical circuit connected to opposite faces of the active piezoelectric element and configured to provide the electrical signal to the active piezoelectric element;
a second electrical circuit connected to opposite faces of the passive piezoelectric element, and including a resistance configured to dissipate the electric energy; and
a housing configured to encase the active piezoelectric element, the passive piezoelectric element, the reflecting layer the first electrical circuit, and the second electrical circuit.

12. A method of manufacturing an ultrasonic sensor, comprising:
mounting, in a holding structure, an active piezoelectric element configured to emit ultrasonic waves in opposite directions; and
mounting, in the holding structure, a passive piezoelectric element configured to absorb an ultrasonic wave emitted by the active piezoelectric element towards the passive piezoelectric element.

13. The method of manufacturing of claim 12, further comprising:
mounting a reflecting layer between the active piezoelectric element and the passive piezoelectric element, the reflecting layer being configured to reflect a part of the ultrasonic wave that is emitted by the active piezoelectric element towards the passive piezoelectric element.

14. The method of manufacturing of claim 12, further comprising:
applying conductive layers on opposite surfaces of the active piezoelectric element and of the passive piezoelectric element, the covered surfaces being perpendicular to the opposite directions.

15. The method of claim 14, further comprising:
connecting the conductive layers applied on the opposite surfaces of the passive piezoelectric element to an electrical circuit including a resistance.

16. The method of claim 14, wherein the passive piezoelectric element is mounted substantially parallel with the active piezoelectric element, and the method further comprises:
mounting one or more mounting components disposed in contact with surfaces of the active piezoelectric element and the passive piezoelectric element that are not covered by the conductive layer, the one or more mounting components being configured to electrically isolate from each other the conductive layers applied on the active piezoelectric element and on the passive piezoelectric element.

17. The method of claim 12, further comprising:
mounting a window element on the active piezoelectric element opposite to the passive piezoelectric element, the window element being configured to have an acoustic impedance matching an acoustic impedance of a fluid inside a borehole.

18. A method of generating mono-directional ultrasonic waves, comprising:
emitting ultrasonic waves that propagate substantially in two different directions by an active piezoelectric element; and
absorbing the ultrasonic waves propagating in one of the two directions by a passive piezoelectric element.

19. The method of claim 18, further comprising:
converting an energy of the absorbed ultrasonic waves into electric energy by the passive piezoelectric element; and
dissipating the electric energy by a resistance in a circuit connected to the passive piezoelectric element.

20. The method of claim 18, further comprising:
reflecting in another one of the two directions, a part of the ultrasonic waves propagating towards the passive piezoelectric element, by a reflecting layer located between the active piezoelectric element and the passive piezoelectric element.
